(19) United States
(12) Patent Application Publication
(10) Pub. No.: US 2025/0212561 A1
(43) Pub. Date: Jun. 26, 2025

(54) LIGHT EMITTING DEVICE IN RED SPECTRAL RANGE

(71) Applicant: KING ABDULLAH UNIVERSITY OF SCIENCE AND TECHNOLOGY, Thuwal (SA)

(72) Inventors: Daisuke IIDA, Thuwal (SA); Kazuhiro OHKAWA, Thuwal (SA)

(21) Appl. No.: 18/846,967

(22) PCT Filed: Mar. 14, 2023
(86) PCT No.: PCT/IB2023/052477

§ 371 Date: Sep. 13, 2024

Related U.S. Application Data
(60) Provisional application No. 63/319,787, filed on Mar. 15, 2022.

(51) Int. Cl. H10H 20/816; H10H 20/825; H10H 29/34

(52) U.S. Cl. CPC H10H 20/8162; H10H 20/825; H10H 29/34

(57) ABSTRACT

A red-light emitting diode, LED, includes an active layer configured to generate red light, the active layer having first and second faces that are opposite to each other, a first barrier layer located on the first face of the active layer, a second barrier layer located on the second face of the active layer, a hole blocking layer located on the first barrier layer, opposite to the active layer, the hole blocking layer being configured to prevent holes to escape from the active layer, a first electrode located on the second barrier layer, and a second electrode located on the hole blocking layer. A bandgap of the hole blocking layer is larger than a bandgap of the first barrier layer.

### CROSS-REFERENCE TO RELATED APPLICATIONS

This application claims priority to U.S. Provisional Patent Application No. 63/319,787, filed on Mar. 15, 2022, entitled “III-NITRIDE SEMICONDUCTOR LIGHT-EMITTING DIODES WITH HOLE BLOCKING LAYERS,” the disclosure of which is incorporated herein by reference in its entirety.

### BACKGROUND OF THE INVENTION

### Technical Field

Embodiments of the subject matter disclosed herein generally relate to a system and method for more efficiently generating red light with a semiconductor device, and more particularly, to an active semiconductor layer that is located next to a hole blocking layer for preventing a hole overflow current away from the active layer, which results in improving the efficiency of the semiconductor device in the red spectral range.

### Discussion of the Background

The InGaN material is an excellent candidate for light-emitting devices in the visible spectral range. This material allows the scientists to adjust its bandgap through material composition adjustment, i.e., adjusting the concentration of one or more of its components. Currently, this topic is of considerable interest as there is a desire to manufacture red, green, and blue (RGB) full-color, micro-light-emitting diodes (LEDs) for next-generation displays. Note that a micro-LED is different from a traditional LED in the sense that the micro-LED is a microscopic LED forming the individual pixel element in a screen. The reduced scale of the micro-LED makes it to behave differently from a traditional LED. The InGaN-based blue and green LEDs have been developed with maximum external quantum efficiencies (EQEs) above 80% and 50%, respectively. These LEDs have been found to work with such high efficiency even when micro-LED fabrication is implemented. In other words, by reducing the size of such materials for micro-LEDs, which is typically used in smartphones, their performance is not affected.

This is not the case for the existing red LEDs. Note that the red light in the context of the LEDs is considered to be in the 600 to 800 nm range. While the red LEDs based on AlGalnP materials have been manufactured to achieve a high EQE, e.g., over 60% by [1], when the dimensions of these materials have been reduced for integration into smart devices, the corresponding micro-LEDs have reported to suffer from a significant efficiency reduction [2-4]. The efficiency of red LEDs is limited due to a physical parameter of the materials such as the high surface recombination and long carrier lifetime [2, 3]. This suggests that nitride-based red micro-LEDs can be realized with a high efficiency rather than that of AlGalnP materials. Therefore, the interest in the development of red micro-LEDs based on nitride materials has increased. However, the efficiency of InGaN-based red LEDs is significantly reduced as the In-content increases in the active region. The low efficiency of the InGaN-based red LEDs is a bottleneck of the full InGaN-based RGB LEDs development.

The major challenge for realizing highly efficient InGaN-based red LEDs is overcoming the fundamental issues of the materials. The major issues for epitaxial growth are presently the low-temperature growth and a large mismatch between consecutive layers. Beside these, high In-content InGaN-based LEDs suffer from a strong quantum-confined Stark effect (QCSE) in the InGaN active regions, which is resulting in peak wavelength shifts and the reduction of the internal quantum efficiencies (IQEs) [5-7].

Several approaches have been proposed to mitigate the lattice mismatch between InGaN active regions and the underlying layers. These approaches are expected to improve the crystalline quality of the InGaN active region because the growth temperature increases due to In pulling effect. InGaN-based red LEDs were demonstrated to grown on pseudo-substrates such as InGaNOS substrate and InGaN on porous GaN porous. Those LED devices have realized a large redshift of the peak emission wavelength compared to those grown on standard GaN templates. Even LEDs grown on GaN/Si substrates need to enhance the In incorporation rate into the InGaN quantum wells (QWs) due to the introduction of the tensile strain in the underlying GaN layer. Recently, 608 nm wavelength InGaN LEDs have been shown to have a peak wall-plug efficiency (WPE) as high as 23.5% at 0.8 A/cm² [8].

The incremental growth temperature of the InGaN is one of key factors to enhance the device's performances. Meanwhile, the structural design of the active region is also important to develop highly efficient InGaN-based LEDs. Previously, several approaches were reported by the inventors [9-11] to reduce defect generation in the InGaN QWs such as strain compensating barrier layers, hybrid QW structures, and thick GaN templates. Those efforts have contributed to the improved InGaN-based red LEDs' performance. However, external quantum efficiencies of the state-of-the-art InGaN-based red LEDs are still far from that of typical blue and green LEDs because of the high-In-content InGaN active layer for red emission has fundamental issues such as a large QCSE and poor material quality.

Thus, there is a need for an improved InGaN-based red micro-LED that has a good emission peak wavelength, and high EQE so that the device is suitable for small-scale applications, like the RGB screen of a smart device.

### SUMMARY OF THE INVENTION

According to an embodiment, there is a red-light emitting diode, LED, that includes an active layer configured to generate red light, the active layer having first and second faces that are opposite to each other, a first barrier layer located on the first face of the active layer, a second barrier layer located on the second face of the active layer, a hole blocking layer located on the first barrier layer, opposite to the active layer, the hole blocking layer being configured to prevent holes to escape from the active layer, a first electrode located on the second barrier layer, and a second electrode located on the hole blocking layer. A bandgap of the hole blocking layer is larger than a bandgap of the first barrier layer.

According to another embodiment, there is a smart device that includes a housing, a screen supported by the housing, the screen including (1) red light emitting diodes, LEDs, (2) blue LEDs, and (3) green LEDs, which together are configured to emit a white light, a processor configured to switch on and off the LEDs of the screen, and a memory connected to the processor and configured to store information. The red LEDs include a corresponding hole blocking layer.

According to yet another embodiment, there is a screen that includes red light emitting diodes, LEDs, configured to emit red light; blue LEDs configured to emit blue light; and green LEDs configured to emit green light. The red, blue and green LEDs together are configured to emit a white light. A red LED of the red LEDs includes an active layer configured to generate red light, the active layer having first and second faces that are opposite to each other; a first barrier layer located on the first face of the active layer; a second barrier layer located on the second face of the active layer; a hole blocking layer located on the first barrier layer, opposite to the active layer, the hole blocking layer being configured to prevent holes to escape from the active layer; a first electrode located on the second barrier layer; and a second electrode located on the hole blocking layer. A bandgap of the hole blocking layer is larger than a bandgap of the first barrier layer.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a traditional red light emitting diode that does not include a hole blocking layer;

FIG. 2 is a schematic diagram of a novel red light emitting diode that includes a hole blocking layer;

FIG. 3 is a schematic diagram illustrating the valence and conduction energies of the red-light emitting diode of FIG. 2;

FIG. 4 is another schematic diagram of the red-light emitting diode that includes the hole blocking layer;

FIG. 5 illustrates the electroluminescence (EL) spectrum of the red LED versus the wavelength;

FIG. 6 illustrates the current dependency of the EL peak wavelength and FWHM versus the injection current;

FIG. 7 illustrates the forward voltage and the light output of the red LED for various injection currents;

FIG. 8 illustrates the output power density for various LEDs, including the red LED;

FIG. 9 illustrates the EQE and WPE for the red LED for various injection currents;

FIG. 10 illustrates another implementation of the red LED of FIG. 2;

FIG. 11 illustrates the energy bandgap for the various layers of the red LED of FIG. 10;

FIG. 12 illustrates the structure of the active layer assembly of the red LED of FIG. 10;

FIG. 13 illustrates yet another implementation of the red LED of FIG. 2;

FIG. 14 illustrates the structure of the active layer assembly of the red LED of FIG. 13;

FIG. 15 illustrates another implementation of the red LED of FIG. 2; and

FIG. 16 illustrates a smart device using the red LED of FIG. 2 for its RGB screen.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a InGaN-based LEDs that emits a red light with an emission peak of about 625 nm. However, the embodiments to be discussed next are not limited such emission peak, or only to InGaN-based LEDs, but may be applied to other LEDs or other emission peaks.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

It will be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

According to an embodiment, highly efficient InGaN-based light-emitting diodes in the red spectral range are grown on conventional c-plane patterned sapphire substrates. An InGaN single quantum well active layer provides the red spectral emission. The LEDs manufactured based on the InGaN active layer obtain a single peak emission and a narrow full-width at half maximum (FWHM), as good as high color purity. An external quantum efficiency, a light-output power, and a forward voltage of the packaged LED with 621 nm peak emission wavelength are, in this embodiment, 4.3%, 1.7 mW and 2.9 V, respectively, for a 20 mA injection current. These diodes can be used in the next generation of micro-LED based displays.

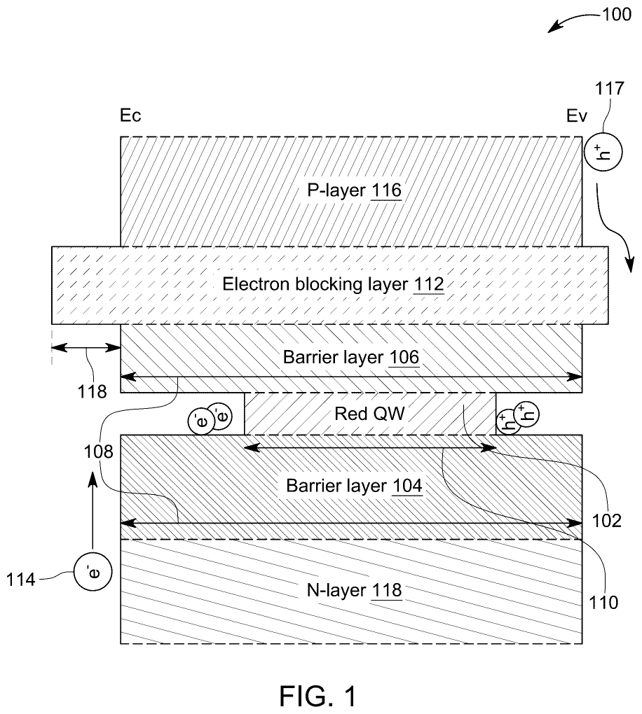

Before detailing the new, highly efficient, InGaN-based light-emitting diodes in the red spectral range, a discussion of a feature that limits the existing LEDs in the red range is discussed. FIG. 1 shows a traditional LED 100 that emits in the red range and this device includes a red emitting quantum well (QW) layer 102, which is sandwiched between barrier layers 104 and 106. The barrier layers 104 and 106 have a larger band gap 108 relative to the band gap of the QW layer 102 (the band gap is the energy difference between the lowest energy level of the conduction band and the maximum energy level of the valence band). FIG. 1 shows the maximum energy Ev of the valence band and also the minimum energy Ec of the conduction band. The difference between these two energies is considered to be the band gap in this and the following figures. By having this specific arrangement in terms of the band gaps, between the QW layer 102 (also called active layer because this is the layer that emits the red light) and the barrier layers 104 and 106, the quantum well effect of the active layer is achieved. The device 100 further includes an electron blocking layer 112, on one side of the QW layer 102, and this layer has the role of preventing the electrons 114 from escaping the active layer and travelling to a first electrode 116, which is a p-layer. The p-layer provides holes 117 to the active layer 102. The device 100 also includes a second electrode 118, which is an n-layer, and this layer provides the electrons 114. Note that the electron blocking layer 112 has the band gap larger than that of the barrier layer 108, and also introduces a band-offset 118 relative to the barrier layer 108, which makes it harder for the electrons 114 to jump over this offset, and thus, harder to escape toward the first electrode 116. Note that if the electrons 114 from the second electrode 118 are allowed to travel to the first electrode 116, they will recombine with the holes 117 at the first electrode and emit light through electroluminescent (EL), which is undesired. The device 100 is ideally configured to combine the electrons with the holes in the QW layer 102, to emit the red light.

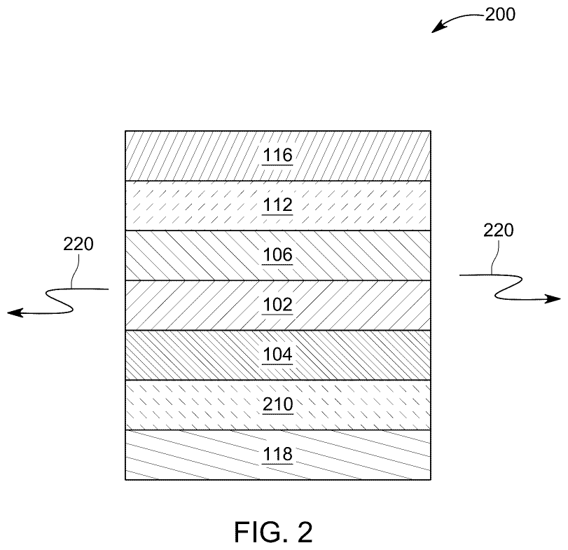

Thus, the inventors have discovered that one of the root causes for the low quantum efficiency of the device 100 is the escape of the holes 117 past the QW layer 102, and the EL recombination, at the second electrode 118, of some of the holes and the electrons. To prevent this effect to occur, the inventors have introduced the structure shown in FIG. 2, which corresponds to a red-light emitting LED 200, and which includes, in addition to the layers shown in FIG. 1, a hole blocking layer 210. The hole blocking layer 210 is located adjacent to the blocking layer 104, on the opposite side of the active layer 102, relative to the electron blocking layer 112. The hole blocking layer 210 prevents the hole overflow current, and thus, it prevents unexpected EL emissions. This means that the red light 220 is mostly emitted at the active layer 102, as schematically indicated in FIG. 2

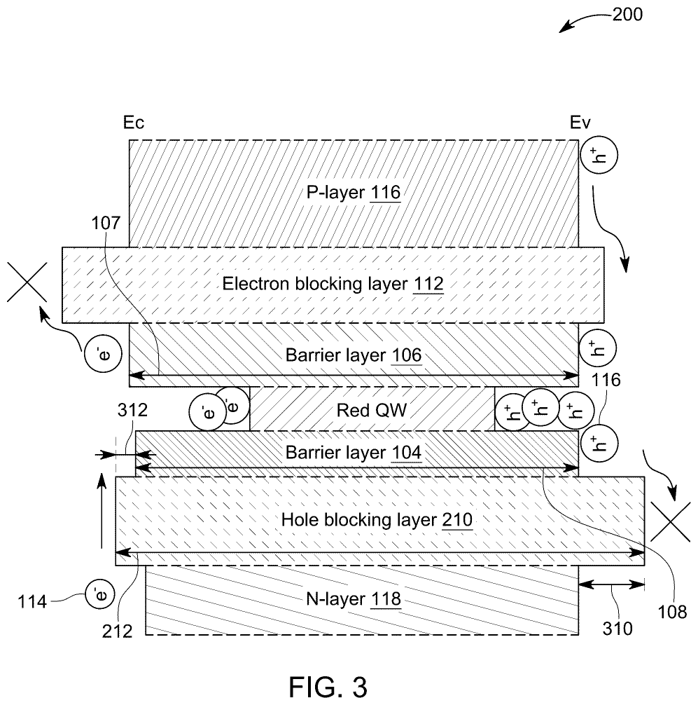

FIG. 3 shows the largest energy Ev of the valence band and the smallest energy Ec of the conduction band for the layers making up the LED 200. It is noted that the hole blocking layer 210 has a largest energy Ev of the valence band smaller than the largest energy Ev of the barrier layer 104, so that an additional band-offset 310 (i.e., the difference in the Ev energy between two adjacent layers, 104 and 210 in this case) is present, which effectively prevents the holes 117 from escaping the QW layer 102 toward the second electrode 118. In this embodiment, the value of the band-offset 310 is selected to be about 350 meV. The term “about” is used in this application to mean plus or minus 20% of the value that is being characterized by this term. However, in another application, the value of the band-offset 310 is selected to be at least 200 meV. Further note that the band-offset 312 introduced by the hole blocking layer 210 at the lowest conduction energy Ec is small, for example, smaller than 100 meV, so that the movement of the electrons 114 from the second electrode 118 to the active layer 102 is not impeded.

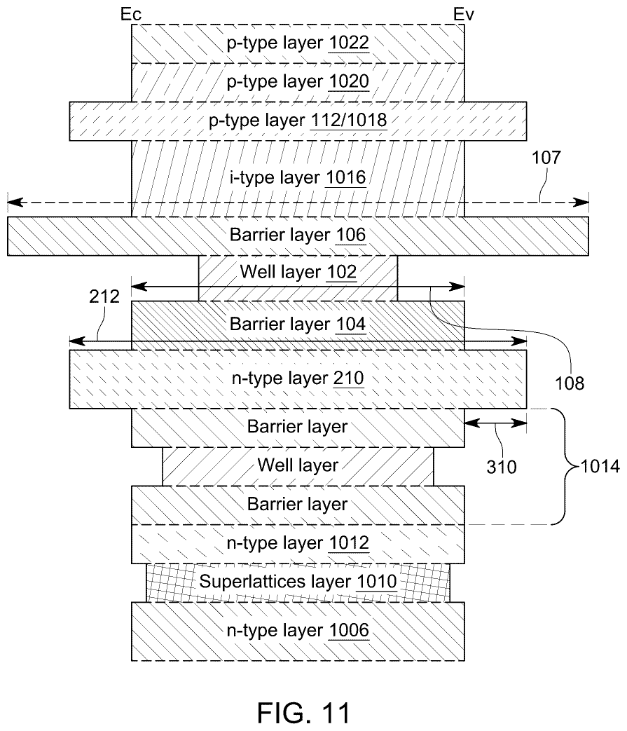

The material composition of the hole blocking layer 210 is also selected so that its bandgap 212 is larger than the bandgap 108 of the barrier layer 104 adjacent to the hole blocking layer 210, as schematically illustrated in FIG. 3. In one variation of this embodiment, the hole blocking layer 210 is also selected so that its bandgap 212 is smaller than the bandgap 107 of the barrier layer 106, adjacent to the hole blocking layer 210, as schematically illustrated later in FIG. 11.

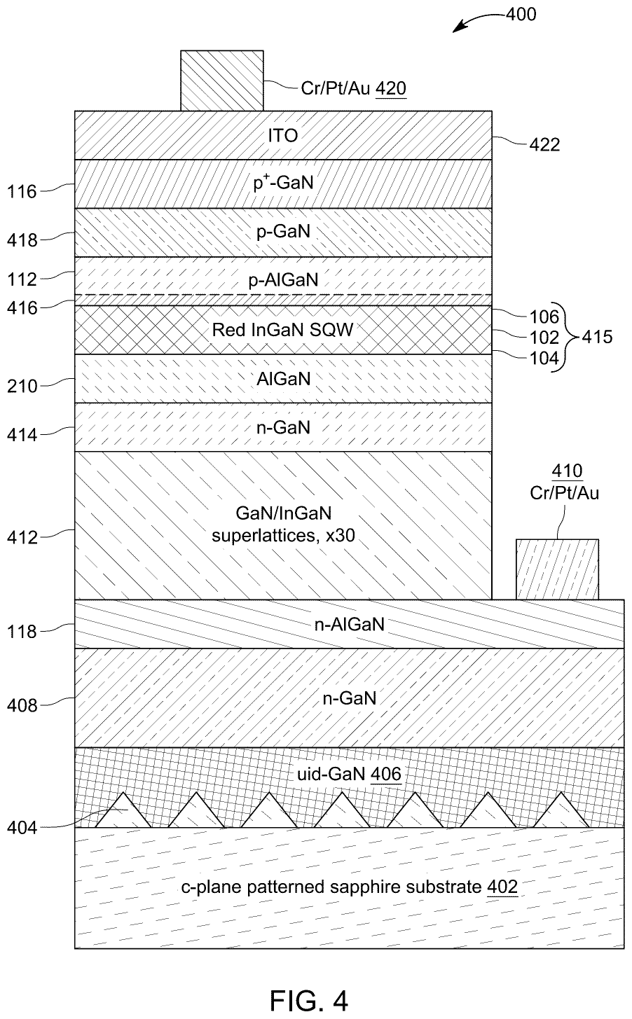

A more detailed implementation of the red LED 200 is shown in FIG. 4 as a red-light emitting diode 400. More specifically, the red-light emitting diode 400 is grown on conventional patterned sapphire substrates by metalorganic vapor phase epitaxy (MOVPE) in a single-wafer horizontal reactor. In this embodiment, a c-plane sapphire substrate 402 with cone-shaped patterns 404 was used, and the patterns 404 were 1.6 μm in height and 2.6 μm in diameter and had a spacing of 0.4 μm. These number as provided to enable one skilled in the art to reproduce this diode, but different numbers may be used and achieve similar results. The InGaN-based LED structure 400 further includes a 2-μm-thick, unintentionally-doped (uid), GaN layer 406 with a low-temperature GaN buffer layer, an 8-μm-thick Si-doped n-GaN layer 408, a 1-μm-thick Si-doped n-Al_{0.03}Ga_{0.97}N contact layer 118, a 30 periods uid-superlattices (SLs) layer 412, which includes 6-nm-thick GaN and 2-nm-thick In_{0.08}Ga_{0.92}N pairs of layers, a 15-nm-thick Si-doped n-GaN layer 414, a hole blocking layer 210 that includes a 2 to 18-nm-thick Si-doped n-Al_{0.13}Ga_{0.87}N, an InGaN active region 415 [which may be made of a 4-nm-thick uid-GaN barrier layers 104 (in one application, only a single barrier layer may be used), a 2.5 to 3.5-nm-thick InGaN SQW active layer 102, and a 1.2-nm-thick uid-AlN/25-nm-thick uid-GaN barrier layers 106 (in one application, only one barrier layer may be used)], a 5-nm-thick Mg-doped p-GaN layer 416, a 15-nm-thick Mg-doped p-Al_{0.11}Ga_{0.89}N electron blocking layer 112, a 100-nm-thick Mg-doped p-GaN layer 418, and a 10-nm-thick heavily Mg-doped p⁺-GaN contact layer 116.

The thick n-GaN underlying layer 408 with the reduction of the in-plane stress can improve the crystal quality of the InGaN active region 415. Note that the n-AlGaN contact layer 118 contributes to a smooth surface morphology even though it has a high Si-doping concentration (>10¹⁹ cm⁻³), and obtains a lower series resistance. The first electrode 410 is formed on the contact layer 118 and the second electrode 420 is formed on the contact layer 116. A transparent indium tin oxide (ITO) layer 422 may be formed between the contact layer 116 and the second electrode 420. The cross-sectional scanning transmittance microscopy (STEM) and the energy-dispersive X-ray spectroscopy (EDS) mappings images (not shown) of the InGaN-based LEDs 400 confirmed the composition uniformity of the materials presented for each epitaxial layer.

The inventors adopted several growth techniques to improve the material quality in the active region. In one application, the LED 400 employed a hybrid MQW structure that inserted an In-content SQW underneath a main InGaN red QW active layer. The InGaN active region consisted of Al(Ga) N barrier layers with band engineering and strain compensating to enhance the light-output power. In addition, the AlN capping layer was employed to prevent the In evaporation during the high-temperature barrier growth.

The LED 400 may be fabricated in this embodiment in the standard face-up configuration. The 100-nm-thick ITO film 422 was deposited on p-layers as a transparent ohmic contact layer using e-beam evaporation. The LED mesas were formed by the inductively coupled plasma etching. The rectangular-shaped LED chips had a mesa width of 250 μm and a mesa length of 850 μm in this embodiment. The emitting area was estimated to be 187000 μm². A combination of Cr (50 nm)/Pt (200 nm)/Au (200 nm) metal structures were deposited as n- and p-pad electrodes 410 and 420. The LED 400 may be packaged with an epoxy resin to enhance the light extraction efficiency.

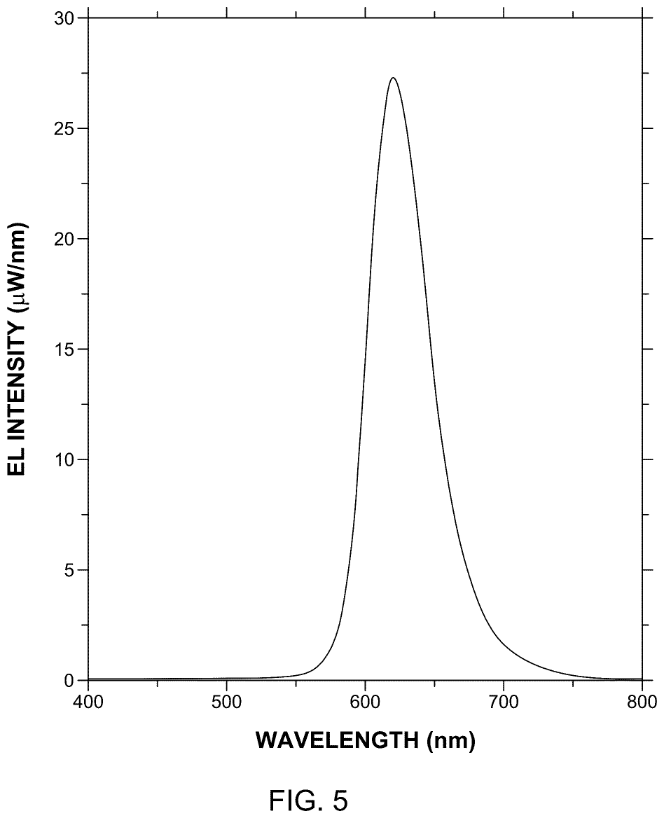

The LED device 400 was characterized by electroluminescence (EL) measurements under direct current (DC) operation at room temperature (RT). The light-output power of the LED 400 was measured by a calibrated integrating sphere. In this regard, FIG. 5 shows the emission spectrum of the InGaN-based LEDs at 20 mA operation. The emission shows a single emission peak at 621 nm, and a full-width at half-maximum (FWHM) of 51 nm. The single emission and narrow FWHM contribute to obtaining a high-purity emission. The emission FWHM of the LED 400 is comparable to state-of-the-art InGaN-based LEDs in the red spectral range.

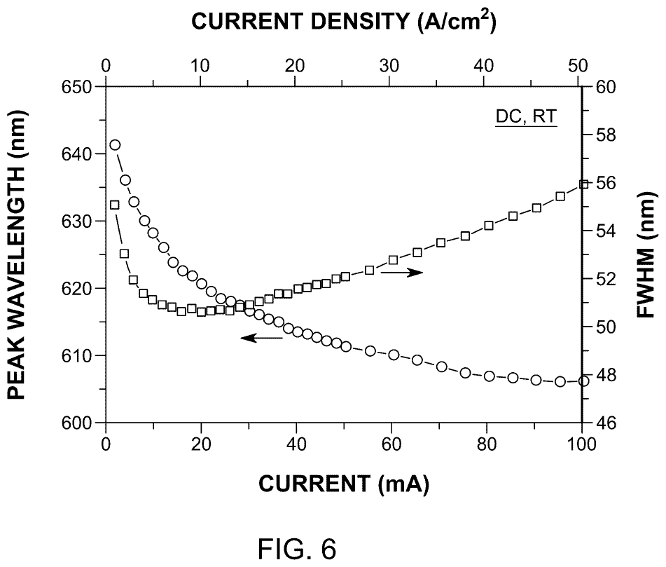

The inventors also characterized the current dependence of EL measurement at RT, as shown in FIG. 6. The peak emission wavelength of the LED 400 exhibited a large shift under a varying injection current from 2 to 100 mA. The large shift behavior is caused by the screening of the internal electric field in the c-plane InGaN QWs with injection current increases. The InGaN red QW indicated a large blue shift compared with blue and green QW emissions while the FWHMs were drastically reduced in the low current range and reached the minimum value of 50 nm at 20 mA. However, the FWHMs started to increase as the injection current exceeded 20 mA due to the heat generation caused by the SRH nonradiative recombination related to defects on the InGaN active region. The increasing of the device temperature should induce the filling of the high-energy localized states due to large In fluctuation in the InGaN QW layer. The defects in the InGaN active region lead to reduced IQE but also FWHM increases. The crystalline quality of the InGaN QW is attributed to a low-temperature growth and a large lattice mismatch. The InGaN-based red LEDs exhibited, in the Commission Internationale de l'Eclairage (CIE) 1931 chromaticity diagram (not shown), the coordinates of (x, y)=(0.685, 0.3121) at 2 mA operation, which was close to Rec. 2020 of (x, y)=(0.708, 0.292). As the injection current increases, the coordinate position of the LEDs shifted away from the point of Rec. 2020 due to the large blue shift by the QCSE. Although the demonstrated InGaN-based LED 400 has a large shift of the color coordinates, all of the points were located at the edge of the chromaticity diagram. The LED 400 also presents a high color purity, which originated from single peak emissions and the narrow FWHMs.

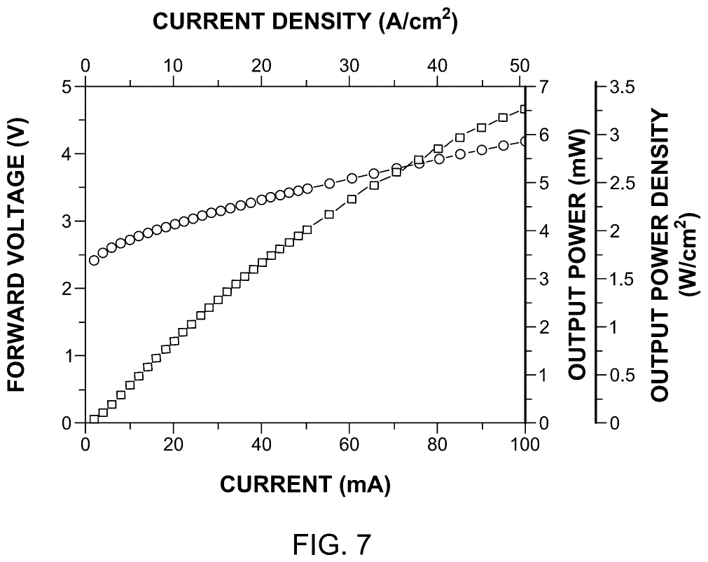

FIG. 7 shows the forward voltage and the light-output power of the InGaN-based LED 400 at different injection currents. The light-output power increased with the injection current. The optoelectrical characteristics of the LEDs presented a good p-n junction. The light-output power of the InGaN-based LED 400 was 1.7 mW at 20 mA injection current. The LED exhibited a low forward voltage of 2.9 V at 20 mA. The number of InGaN SLs periodicity increases from 11 to 30, which means the V-pits dimension increases. According to the literature, the V-pit structures can enhance the hole injection into the active layer via the sidewalls. Therefore, the larger V-pits contribute to obtaining the low forward voltage operation.

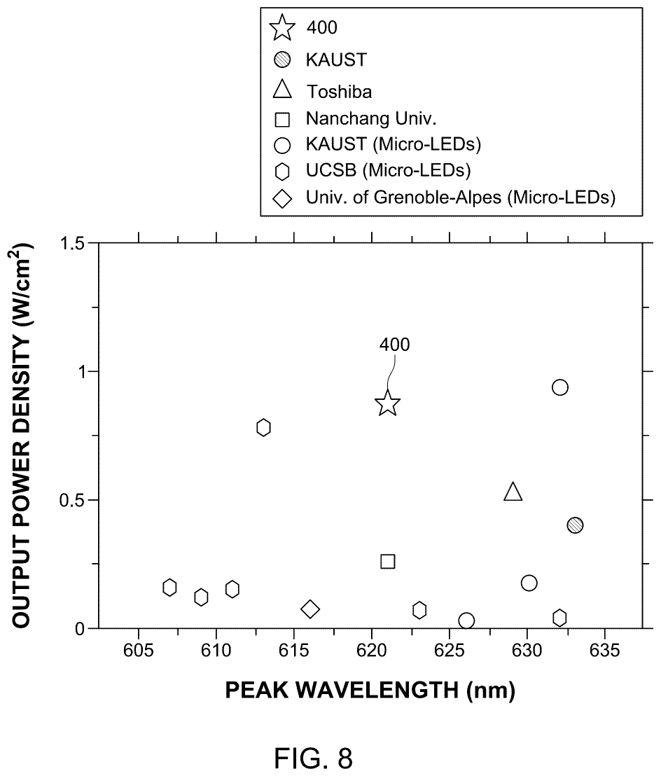

The output power density with different peak wavelengths were compared with other works, as shown in FIG. 8. The star in this figure corresponds to the LED 400.

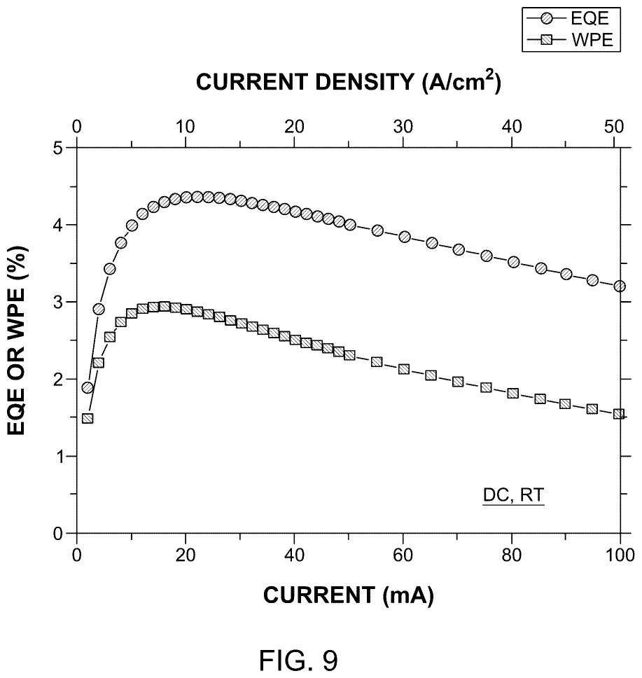

The inventors also calculated the EQEs and WPEs of the LEDs at various injection currents as shown in FIG. 9. The peak EQE and WPE were 4.3% and 2.9% at 20 mA (10 A/cm²), respectively. The peak EQE value of the InGaN-based red LED 400 at ≥10 A/cm² is considered to be high in the red emission range over 620 nm emission peak wavelength. Note that the known devices have some difficulties for achieving these results. In general, the InGaN-based LEDs have difficulties in obtaining a peak emission over 620 nm at high current density operation due to the large blue shift. The In-content in the InGaN QWs is needed to increase the emission wavelength.

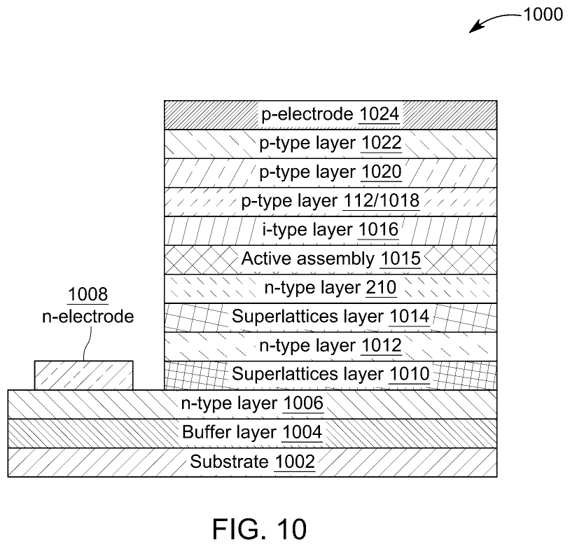

A variation of the implementation of the red-light emitting device 200 is now discussed with regard to FIG. 10. The red-light emitting device 1000 includes an n-side contact layer, an active layer, and a p-side contact layer in this order. These layers can be made by epitaxial growth, for example, a crystal growth method such as metalorganic vapor-phase epitaxy. All the parameters discussed herein, such as the type of material, thickness, structure, and composition are just examples to enable those skilled in the art, and these features may be varied for achieving variations of the device 1000. All III-nitride layers are formed by controlling a composition of a group III element. The compositions are defined by the values of x, y, and z of AlₓGa_{y}In_{z}N, where x+y+z=1. One or more layers discussed herein can incorporate one or more of other atoms, for example, C, Si, Ge, Sn, Be, Mg, Ca, Sr, O, S, Se, Te, Zn, Cd, P, As, Sb, and so on. The concentration of the added atoms may be above 1×10¹⁶ cm⁻³.

LED 1000 includes a substrate 1002 formed of a material which is not limited to Si or similar materials, as long as a semiconductor layer can be grown on its upper surface. In one application the substrate is a sapphire substrate, but it may include any of SiC, GaN, AlN, Diamond, ZnO, ZnS, ScAlMgO₄, Ga₂O₃, LiAIO₂, GaAs, etc. The substrate 1002 can be removed when the LED 1000 is ready. The Ill-nitride epi-layers are allowed to use an arbitrary growth plane such as {0001}, {10-10}, {11-20}, {11-22}, {10-12}, {10-13}, {10-11}, {20-21}, and so on.

Next, a buffer layer 1004 is located over the substrate 1002. When using a different kind of substrate, such as sapphire, it is preferable to provide a buffer layer which is a low-temperature (LT) growth layer. By interposing the buffer layer, the crystallinity of the semiconductor layer grown thereon becomes better. For example, the buffer layer can be formed by GaN, AlN, and/or AlGaN. However, when using a GaN as the substrate 1002 instead of the heterogeneous substrate, the buffer layer is not necessary. The buffer layer 1004 can be removed when the LED 1000 fabrication is finalized.

A contacting layer 1006 is formed over the buffer layer 1004. The contacting layer 1006 may be an n-type layer. Various materials may be used for the n-type layer 1006, for example, GaN and AlGaN. In some applications, n-GaN has often been used as the n-layer. The n-type layer 1006 is the n-side contacting layer where the n-electrode 1008 is provided. A doping composition for the contacting layer 1006 may be from 1×10¹⁶ to 1×10²¹ cm⁻³. In this embodiment, the n-type layer 1006 is not necessarily required to have a uniform doping and/or the material composition noted above. A thickness of this layer is preferable to be from 10 to 20,000 nm, more preferably between 100 to 10,000 nm. The n-electrode 1008 may include various materials and may have various structures. For example, the n-electrode can include layers of Cr/Pt/Au.

Next, a superlattice layer 1010 is formed on the n-type layer 1006. The first layer and the last layer of the superlattice layer may include any known material used for this purpose. The superlattice layer 1010 may include plural pairs of a barrier layer and a well layer. The barrier layer may be made of GaN or InGaN and the well layer may be made of InGaN. The superlattice layer 1010 needs to include In atoms in this embodiment. For example, the well layer may have an In composition from 0 to 1. The In composition is preferable to be from 0.05 to 0.4, and more preferably between 0.1 to 0.2. The In distribution may not be a uniform composition. In one application, the In atoms may be added to the barrier layer, but in this case, the In amount should be less than that of the well layer. In one application, the barrier layers and the well layers of the superlattices layer 1010 are not intentionally doped (i.e., they are undoped) with n-type impurities. However, at least one of the barrier layers and the well layers may be doped with an n-type impurity to the extent that their characteristics are not impaired. This layer can have n-type doping and the doping composition can be from 1×10¹⁶ to 1×10²¹ cm⁻³, with or without uniform doping.

In one application, the superlattices layer 1010 can be used as a bulk layer. For example, this layer may include an InGaN bulk layer with the average In doping so that a composition of the superlattices layer is given by InGaN/GaN. The total thickness of the layer 1010 is preferable to be from 10 to 10,000 nm, more preferably between 10 to 1,000 nm. In the case of the superlattices structure, the well layer's thickness is preferable to be from 0.3 to 100 nm, more preferably between 0.3 to 10 nm. The barrier layer's thickness is preferable to be from 0.3 to 100 nm, and more preferably between 0.3 to 10 nm.

Next, an n-type layer 1012 is located over the superlattices layer 1010. The n-layer 1012 may include GaN and/or InGaN. The n-type doping composition is, in one application, between 1×10¹⁶ and 1×10²¹ cm⁻³. In another application, the doping composition is preferable between 1×10¹⁷ to 1×10¹⁹ cm⁻³, and more preferably between 1×10¹⁸ to 1×10¹⁹ cm⁻³. In one application, the n-layer 1012 does not need to have a uniform doping. The thickness of this layer is preferable to be from 1 to 1000 nm, and more preferably, between 10 to 100 nm. In one application, this layer can be omitted.

A superlattices layer 1014 is located over the n-type layer 1012. The superlattices layer 1014 may include plural pairs of a barrier layer and a well layer. In one application, the superlattices layer 1014 may include a single pair of the barrier layer and the well layer. The first layer and the last layer of the superlattices layer 1014 may include various materials. A total thickness of the barrier layers is preferably larger than that of the well layers. As a result, the crystallinity of the layers can be improved. The barrier layer may be made of GaN or InGaN and the well layer may be made of InGaN. In one application, the superlattices layer does not include In atoms. In one application, the well layer may have an In composition from 0 to 1. It is preferable to be from 0.05 to 0.4, more preferably between 0.1 to 0.3. The In distribution may not be a uniform composition. In another application, the In atoms can be added to the barrier layer, but in this case, the In atoms should be less than that of the well layer.

Each InGaN well layer may have a different In-composition from another well layer when the overall structure of the superlattices layer 1014 includes a stack of barrier and well layers. In one application, the In-composition in these layers can be changed along a growth direction. The In-composition of the InGaN well layers needs to be smaller than that of the active layers. In one application, the barrier layers and the well layers are not intentionally doped (i.e., undoped) with n-type impurities. However, at least one of the barrier layers and the well layers may be doped with an n-type impurity to the extent that their characteristics are not impaired. If these layers are doped, the n-type doping may be from 1×10¹⁶ to 1×10²¹ cm⁻³. The layers may have a uniform or non-uniform doping. A total thickness of the superlattices layer 1014 is preferable to be from 10 to 10,000 nm, more preferably between 10 to 1,000 nm. The well thickness is preferable to be from 0.3 to 100 nm, more preferably between 0.3 to 10 nm. The barrier thickness is preferable to be from 0.3 to 100 nm, more preferably between 0.3 and 10 nm. The superlattices layer 1014 is preferable to be inserted underneath of the active layer for improving the crystalline quality of the active layer. The same is true for the n-type layer 1012. In other words, the purpose of the n-type layer 1012 and the superlattices layer 1014 is to improve the quality of the crystalline structure of the active layer.

Next, the hole blocking layer 210 is placed over the superlattices layer 1014. The hole blocking layer 210 is an n-type layer in this embodiment. The material of the n-layer 210 may be AlGaN, but other materials may be used. The n-type layer 210 may have an Al doping composition from 1×10¹⁶ to 2×10²² cm⁻³ (density of Ga in GaN is 4.4×10²² cm⁻³, so Al 2×10²² means Al content of 46% Al_{0.46}Ga_{0.54}N). In one application, the Al doping composition is from 1×10²⁰ to 1×10²² cm⁻³, and in still another application, it is between 1×10²¹ and 8×10²¹ cm⁻³ (i.e., Al content between 2% and 18%). In this embodiment, the n-type layer 210 may have a uniform or non-uniform doping. The thickness of the layer 210 may be from 1 to 1000 nm, and more preferably between 10 to 100 nm.

The composition of the hole blocking layer 210 is selected so that its bandgap energy is, at a minimum, larger than the bandgap energy of the active layer 102, which is located on top of the hole blocking layer 210. The various bandgaps of the layers of the LED 1000 are illustrated in FIG. 11. As discussed with regard to FIG. 3, a band-offset 310 between the layer 210 and a barrier layer 104, located directly on top of the layer 210, and directly under the active layer 102, is at least 200 meV. In addition to the band-offset 310 condition noted above, in various applications, one or more of the following conditions may also be implemented when selecting the composition of the hole blocking layer 210 (however, note that these additional conditions optional, i.e., they may not be implemented in the device): (1) the bandgap energy is larger than that of the n-type layer 1006, and/or (2) the bandgap energy is larger than that of the n-type layer 1012, and/or (3) the bandgap energy is larger than that of the barrier layer of the superlattices layer 1014, and/or (4) the bandgap energy is larger than that of the barrier layer 104, and/or (5) the bandgap energy is smaller than that of the barrier layer 106, and/or (6) the bandgap energy is larger than that of a i-type layer 1016, which is located on top of the barrier layer 106, and/or (7) the bandgap energy is larger than that of a p-type layer 1020, and/or (8) the bandgap energy is larger than that of a p-type layer 1022. In one embodiment, the hole blocking layer 210 may be implemented as a superlattice layer. For example, this layer may include an AlGaN layer and a GaN layer with the average Al composition of the AlGaN bulk layer. However, in one application, the hole blocking layer is a AlGaN bulk layer.

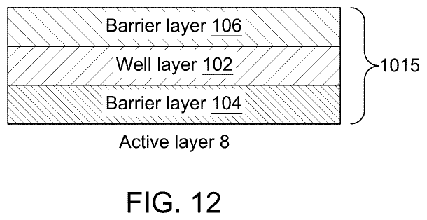

An active layer assembly 1015 is shown in FIG. 10 being located directly on top of the hole blocking layer 210. Note that FIG. 12 shows the active layer assembly 1015 including the active layer 102, which is sandwiched between barrier layers 104 and 106. In this application, the term “active layer” is used to refer to layer 102 or to active layer assembly 1015 (which includes at least three layers, one of which is the active layer 102). The structure of the active layer assembly 1015 may include a single quantum well structure (SQW) having a single well layer or multiple quantum well structure (MQW), having a plurality of well layers and barrier layers. FIG. 12 illustrates the structure of SQW. For MQW structures, the stacking order may start either from the well layer 102 or from the barrier layers 104, 106, and it may be similarly terminated with the well layer 102 or the barrier layers 104, 106. For example, the active layer assembly 1015 may include a first barrier layer 104 made of GaN, a second barrier layer 106 made of AlN, and a well layer 102 made of InGaN. The barrier layers may be made of multiple stacking structures using, for example, AlN, GaN, AlGaN, and InGaN compositions. In one application, the total thickness of the first barrier layer 104 is preferably larger than that of the well layer 102. As a result, the crystallinity of the entire active assembly layer can be improved. The total thickness of the barrier layers is preferable to be from 10 to 1000 nm. In one application, this thickness is from 10 to 200 nm. The thicker barrier layer 104 can improve the crystalline quality of epi-layers grown on it. The well thickness is preferable to be from 0.3 to 5 nm, more preferably between 1 to 3.5 nm. The total barrier thickness is preferable to be from 0.3 to 100 nm, more preferably between 1 to 30 nm. In one application, it is preferable that the barrier layers 104, 106 and the well layer 102 are not intentionally doped (i.e., they are undoped) with n-type impurities. However, at least one of the barrier layers and the well layers may be doped with an n-type impurity to the extent that their characteristics are not impaired. In the present application, the term “undoped” means less than 1×10¹⁷ cm⁻³. When using n-type doping, the preparation layers are not necessarily required to have uniform doping.

The i-type layer 1016 is provided over the active layer assembly 1015 and this layer may be made of various materials, for example, GaN and/or AlGaN. It is preferable that the i-type layer 1016 is not intentionally doped. However, if this layer is doped, it can be doped with p-type impurities. Mg-doping is often used as a p-type layer in Ill-nitride materials. The doping composition may be from 1×10¹⁶ to 1×10²¹ cm⁻³. In this embodiment, the i-type layer 1016 does not have a uniform doping. The thickness of this layer is preferable to be from 1 to 1000 nm, more preferably between 5 to 50 nm. However, the i-type layer 1016 is optional.

A p-type layer 1018 is located over the layer 1016. The p-type layer 1018 may be made of AlGaN, but other materials may be used. In general, the p-type AlGaN has been used as an electron blocking layer. Thus, this layer corresponds to layer 112 of the LED 200 shown in FIG. 3. The doping composition for the layer 1018 may be from 1×10¹⁶ to 1×10²¹ cm⁻³. In this embodiment, the p-type layer 1018 does not have a uniform doping. The thickness of the layer is preferable to be from 1 to 1000 nm, more preferably between 10 to 100 nm. In one application, the p-type layer 1018 is optional.

A p-type layer 1020 is located over the layer 1018 and this layer may be made of GaN and/or AlGaN. The layer 1020 may have a doping composition from 1×10¹⁶ to 1×10²¹ cm⁻³ and may have a uniform or non-uniform doping. The thickness of this layer is preferable to be from 1 to 1000 nm, more preferably between 10 to 200 nm. The p-type layer 1020 is optional in this embodiment. If present, the layers 1018 and 1020 improve the device performance, i.e., promote high EQE, low leakage current, and long lifetime.

A p-type layer 1022 is located over the layer 1020 and provides a support for the p-electrode 1024. The layer 1022 may include Mg-doped GaN. The doping composition of this layer may be from 1×10¹⁷ to 1×10²¹ cm³, and may have a uniform or non-uniform doping. The thickness of this layer is preferable to be from 1 to 1000 nm, more preferably between 10 to 100 nm.

The p-electrode 1024 may be made of many materials. In the case of a face-up configuration of the LED 1000, the p-electrode 1024 includes, for example, a transparent electrode made of indium tin oxide (ITO) provided on the entire surface of the p-type layer 1022 and a second pad electrode made of Ni/Ag/Ti/Au provided on a part of the transparent electrode. In the case of a flip-chip configuration, the p-electrode 1024 includes, for example, a transparent electrode made of ITO provided on the entire surface of the p-type layer 1022 and a pad electrode made of Ni/Ag/Ti/Au provided on the entire surface of the transparent electrode. However, a transparent electrode is not necessarily required in this embodiment.

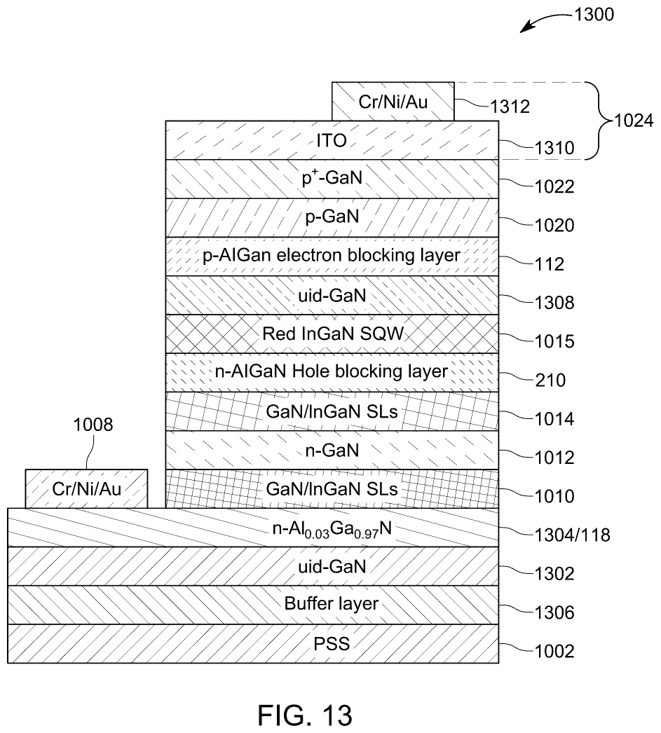

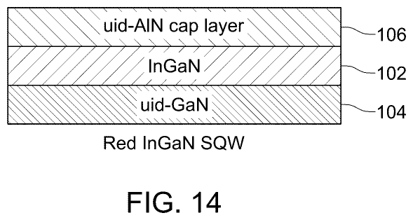

In one application, the light-emitting devices discussed above can be further processed to be removed from their substrates by laser lift-off or wet etching. These lift-off techniques can be provided by wafer-scale or chip on board. For example, a face-up InGaN-based light-emitting diode 1300 can be implemented as shown in FIG. 13. In this embodiment, the LED 1300 includes an undoped GaN layer 1300 (2 μm thick) and n-Al_{0.03}Ga_{0.97}N layer 1304 (1 μm thick, Si-2×10¹⁹ cm⁻³) grown on a sapphire substrate 1002 with an LT-buffer GaN layer 1306 (20 nm thick). The n-Al_{0.03}Ga_{0.97}N layer 1304 corresponds to the n-contacting layer 118 in FIG. 3. FIG. 3 further shows an undoped, 30 periods, In_{0.06}Ga_{0.94}N (2 nm)/GaN (6 nm) superlattices layer 1010 located on the layer 1304, followed by an n-GaN layer 1012 (thickness 15 nm, Si=3×10¹⁸ cm⁻³), and a superlattices layer 1014, that includes pairs of (1) an undoped In_{0.2}Ga_{0.8}N (2 nm thick) single QW with (2) undoped GaN (3 nm thick) barrier. An n-Al_{0.1}Ga_{0.9}N layer is located on top of the superlattices layer 1014, and acts as the hole blocking layer 210, followed by an undoped In_{0.34}Ga_{0.66}N (2.5 nm thick) single QW layer 102 with an undoped AlN (1 nm) barrier layer 106 and an undoped GaN (20 nm thick) barrier layer 104 (see FIG. 14) acting as the active layer assembly 1015. Next, an undoped-GaN layer 1308 (10 nm thick) is located over the active layer assembly 1015, followed by a p-Al_{0.1}Ga_{0.9}N layer (15 nm thick, Mg=4×10¹⁹ cm³ doping) that acts as the electron blocking layer 112, a p-GaN layer 1020 (100 nm thick, Mg=2×10¹⁹ cm⁻³), and a p-GaN layer 1022 (10 nm thick, Mg=1.5×10²⁰ cm⁻³), acting as the p-contacting layer 116. Note that all the numbers and ranges provided in these embodiments are provided as an example and any variations of them by plus or minus 20% are expected to achieve the same effects. A p-contact electrode 1024 includes the ITO layer 1310, and both the n-contact electrode 1312 and the p-pad electrode 1008 include Cr/Ni/Au.

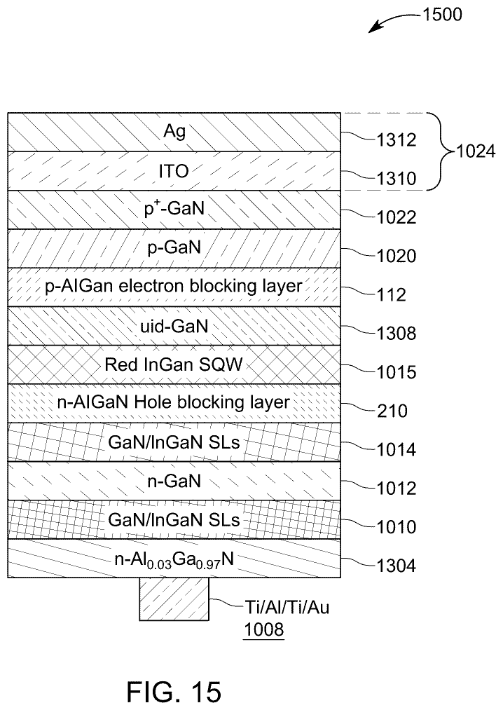

Another possible implementation of the LED 200, as a flip-chip InGaN-based light-emitting diode 1500 is shown in FIG. 15. FIG. 15 shows the flip-chip InGaN-based red LED 1500 with the hole blocking layer 210. The details of the epitaxial layers is the same as in the LED 1300 shown in FIG. 13 and discussed above. The substrate 1002 and buffer layer 1306 have been removed and thus, the n-contact electrode 1024 includes ITO/Ag layers 1310, 1312 and the p-contact electrode 1008 includes Ti/Al/Ti/Au, which have been located directly on the layer 1304.

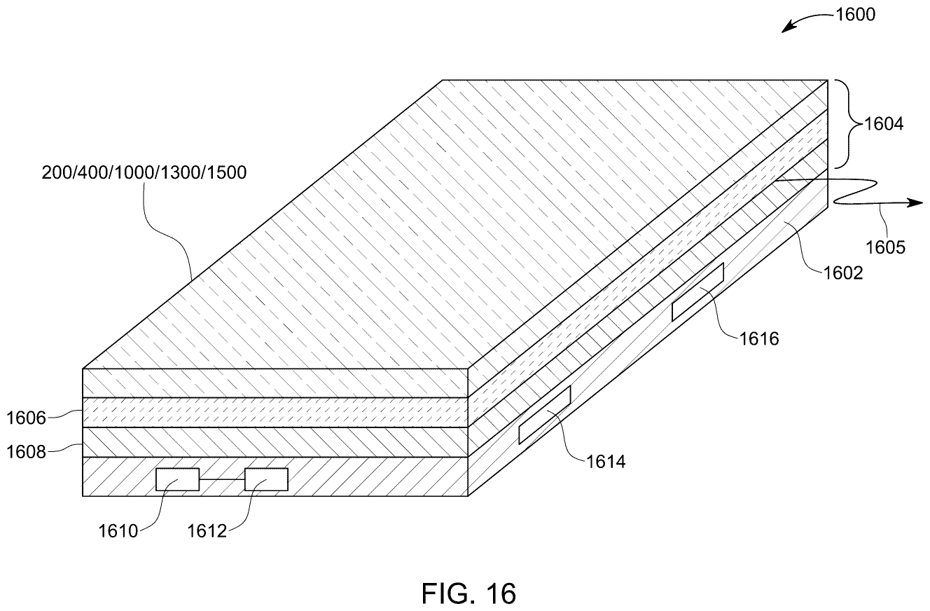

The InGaN-based LEDs discussed above may be used for the next generation of displays by micro-LED chips because the III-nitride materials can emit RGB colors by tuning the bandgap energy. Owing to their high efficiency, brightness, and stability, Ill-nitride-based micro-LEDs may be implemented in smart devices, for example, smartphones, smartwatches or panels, virtual reality (VR), and augmented reality (AR) glasses, and so on. Such a novel smart device 1600 is schematically illustrated in FIG. 16 and has a housing 1602 that supports a screen 1604. The screen 1604 may include any of the red-light emitting LEDs 200, 400, 1000, 1300, and 1500, a blue light emitting LED 1606, and a green light emitting LED 1608 (other stacking is also possible or other order), all located in top of each other so that white light 1605 or any other light may be emitted by the screen 1604, when the corresponding LEDs are activated. The housing 1602 includes a processor 1610 and a memory 1612 for controlling the screen and what LEDs to be switched on and off and when. The housing further includes a power source 1614, for supplying the LEDs, the processor and the memory with electrical power. The housing also includes an input/output interface 1616 for allowing the operator to interact with the processor and screen of the smart device. Other elements that are typically found in a smart phone or glass device or smart watch may be present in the smart device 1600.

The disclosed embodiments provide an InGaN-based LED that emits in the red spectral range and includes a hole blocking layer for preventing the holes from escaping the active layer, toward the electron supplying electrode, which results in a high external quantum efficiency. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] M. Broell, P. Sundgren, A. Rudolph, W. Schmid, A. Vogl, and M. Behringer, Proc. of SPIE 9003, 90030L (2014).
[2] Y. Zhao, J. Liang, Q. Zeng, Y. Li, P. Li, K. Fan, W. Sun, J. Lv, Y. Qin, Q. Wang, J. Tao, and W. Wang, Opt. Express 29, 20217 (2021).
[3] J.-T. Oh, S.-Y. Lee, Y.-T. Moon, J. H. Moon, S. Park, K. Y. Hong, K. Y. Song, C. Oh, J.-I. Shim, H.-H. Jeong, J.-O. Song, H. Amano, and T.-Y. Seong, Opt. Express 26, 11194 (2018).
[4] M. S. Wong, J. A. Kearns, C. Lee, J. M. Smith, C. Lynsky, G. Lheureux, H. Choi, J. Kim, C. Kim, S. Nakamura, J. S. Speck, and S. P. DenBaars, Opt. Express 28, 5787 (2020).
[5] P. Li, H. Li, Y. Yang, H. Zhang, P. Shapturenka, M. Wong, C. Lynsky, M. Iza, M. J. Gordon, J. S. Speck, S. Nakamura, and S. P. DenBaars, Appl. Phys. Lett. 120, 041102 (2022).
[6] D. lida, Z. Zhuang, P. Kirilenko, M. Velazquez-Rizo, and K. Ohkawa, Appl. Phys. Express 13, 031001 (2020).
[7] J.-I. Hwang, R. Hashimoto, S. Saito, and S. Nunoue, Appl. Phys. Express 7, 071003 (2014).
[8] S. Zhang, J. Zhang, J. Gao, X. Wang, C. Zheng, M. Zhang, X. Wu, L. Xu, J. Ding, Z. Quan, and F. Jiang, Photonics Res. 8, 1671 (2020).
[9] D. lida, Z. Zhuang, P. Kirilenko, M. Velazquez-Rizo, M. A. Najmi, and K. Ohkawa, Appl. Phys. Lett. 116, 162101 (2020).
[10] D. lida, S. Lu, S. Hirahara, K. Niwa, S. Kamiyama, and K. Ohkawa, J. Cryst. Growth 448, 105 (2016).
[11] D. lida, K. Niwa, S. Kamiyama, and K. Ohkawa, Appl. Phys. Express 9, 111003 (2016).

1. A red-light emitting diode, LED, comprising:
an active layer configured to generate red light, the active layer having first and second faces that are opposite to each other;
a first barrier layer located on the first face of the active layer;
a second barrier layer located on the second face of the active layer;
a hole blocking layer located on the first barrier layer, opposite to the active layer, the hole blocking layer being configured to prevent holes to escape from the active layer;
a first electrode located on the second barrier layer; and
a second electrode located on the hole blocking layer,
wherein a bandgap of the hole blocking layer is larger than a bandgap of the first barrier layer.

2. The LED of claim 1, wherein a band offset between the hole blocking layer and the first barrier layer is at least 200 meV.

3. The LED of claim 1, further comprising:
an electron blocking layer located between the second barrier layer and the first electrode.

4. The LED of claim 1, wherein the active layer is made of Al, Ga, and N atoms.

5. The LED of claim 4, wherein the hole blocking layer is made of Al, Ga, and N atoms.

6. The LED of claim 4, wherein a thickness of the active layer is about 2.5 nm and a thickness of the hole blocking layer is about 2 nm.

7. The LED of claim 1, wherein the active layer is made of only In, Ga and N atoms.

8. The LED of claim 1, wherein an external quantum efficiency of the active layer is about 4.3% due to the hole blocking layer.

9. The LED of claim 1, wherein the bandgap of the hole blocking layer is smaller than a bandgap of the second barrier layer.

10. A smart device comprising:
a housing;
a screen supported by the housing, the screen including red light emitting diodes, LEDs, blue LEDs, and green LEDs, which together are configured to emit a white light;
a processor configured to switch on and off the LEDs of the screen; and
a memory connected to the processor and configured to store information,
wherein the red LEDs include a corresponding hole blocking layer.

11. The smart device of claim 10, wherein a red LED of the red LEDs comprises:
an active layer configured to generate red light, the active layer having first and second faces that are opposite to each other;
a first barrier layer located on the first face of the active layer;
a second barrier layer located on the second face of the active layer;
the hole blocking layer located on the first barrier layer, opposite to the active layer, the hole blocking layer being configured to prevent holes to escape from the active layer;
a first electrode located on the second barrier layer; and
a second electrode located on the hole blocking layer,
wherein a bandgap of the hole blocking layer is larger than a bandgap of the first barrier layer.

12. The smart device of claim 11, wherein a band offset between the hole blocking layer and the first barrier layer is at least 200 meV.

13. The smart device of claim 11, wherein the red LED further comprises:
an electron blocking layer located between the second barrier layer and the first electrode.

14. The smart device of claim 11, wherein the active layer is made of Al, Ga, and N atoms.

15. The smart device of claim 14, wherein the hole blocking layer is made of Al, Ga, and N atoms.

16. The smart device of claim 14, wherein a thickness of the active layer is about 2.5 nm and a thickness of the hole blocking layer is about 2 nm.

17. The smart device of claim 12, wherein the active layer is made of only In, Ga and N atoms.

18. The smart device of claim 11, wherein an external quantum efficiency of the active layer is about 4.3% due to the hole blocking layer.

19. The smart device of claim 11, wherein the bandgap of the hole blocking layer is smaller than a bandgap of the second barrier layer.

20. A screen comprising:
red light emitting diodes, LEDs, configured to emit red light;
blue LEDs configured to emit blue light; and
green LEDs configured to emit green light,
wherein the red, blue and green LEDs together are configured to emit a white light, and
wherein a red LED of the red LEDs comprises:
an active layer configured to generate red light, the active layer having first and second faces that are opposite to each other;
a first barrier layer located on the first face of the active layer;
a second barrier layer located on the second face of the active layer;
a hole blocking layer located on the first barrier layer, opposite to the active layer, the hole blocking layer being configured to prevent holes to escape from the active layer;
a first electrode located on the second barrier layer; and
a second electrode located on the hole blocking layer,
wherein a bandgap of the hole blocking layer is larger than a bandgap of the first barrier layer.
